(19) United States
(12) Patent Application Publication
(10) Pub. No.: US 2018/0358480 A1
(43) Pub. Date: Dec. 13, 2018

(54) MULTIJUNCTION SOLAR CELLS HAVING AN INTERDIGITATED BACK CONTACT PLATFORM CELL

(71) Applicant: Alliance for Sustainable Energy, LLC, Golden, CO (US)

(72) Inventors: Pauls Stradins, Golden, CO (US); Adele Clare Tamboli, Golden, CO (US)

(21) Appl. No.: 16/002,255

(22) Filed: Jun. 7, 2018

Related U.S. Application Data
(60) Provisional application No. 62/516,792, filed on Jun. 8, 2017.

(51) Int. Cl. H01L 31/02; H01L 31/0725; H01L 31/0304; H01G 9/20; H01L 31/0224

(52) U.S. Cl. CPC H01L 31/02008; H01L 31/0725; H01L 31/022441; H01G 9/2009; H01L 31/0304

(57) ABSTRACT

Multijunction solar cells having an interdigitated back contact (IBC) platform cell are provided. According to an aspect of the invention, a multijunction device includes a top cell; a platform cell that is electrically connected to the top cell, wherein the platform cell comprises an interdigitated contact layer having a first contact of a first semiconductor type and a second contact of a second semiconductor type; a first bottom cell that is electrically connected to the first contact; a first electrical connection that is configured to deliver a first current from the first bottom cell to the second contact; and a second electrical connection that is configured to deliver a second current from the top cell to the second contact. The platform cell is positioned between the top cell and the first bottom cell.

### CROSS-REFERENCE TO RELATED APPLICATIONS

This application claims priority under 35 U.S.C. § 119 to U.S. Provisional Patent Application No. 62/516,792, filed on Jun. 8, 2017, the contents of which are hereby incorporated by reference in its entirety.

### CONTRACTUAL ORIGIN

The United States Government has rights in this invention under Contract No. DEAC36-08GO28308 between the United States Department of Energy and the Alliance for Sustainable Energy, LLC, the Manager and Operator of the National Renewable Energy Laboratory.

### BACKGROUND

The present invention relates to multijunction solar cells having an interdigitated back contact (IBC) platform cell. A multijunction solar cell includes multiple p-n junctions that have different bandgaps, in order to absorb radiation from different portions of the electromagnetic spectrum. In a typical multijunction solar cell, the individual cells are connected in series, forming a monolithic two-terminal device. The individual cell voltages are additive, while the individual cell currents should match for the best performance. However, each cell's current is defined by its selectively absorbed part of the electromagnetic spectrum. The latter is limited by the choice of cell absorber materials, which may be constrained by material compatibility issues. It is thus difficult to match the photogenerated currents exactly, which may lead to efficiency loss. One way to circumvent this problem would be to contact each cell separately, but too many terminals and highly conductive intermediate grid structures present major technological and economic problems. Therefore, it would be advantageous to provide a structure that relaxes the current-matching requirements without contacting and operating each individual cell separately.

### SUMMARY

Exemplary embodiments of the invention provide multijunction solar cells having an IBC platform cell. According to an aspect of the invention, a multijunction device includes a top cell; a platform cell that is electrically connected to the top cell, wherein the platform cell comprises an interdigitated contact layer having a first contact of a first semiconductor type and a second contact of a second semiconductor type; a first bottom cell that is electrically connected to the first contact; a first electrical connection that is configured to deliver a first current from the first bottom cell to the second contact; and a second electrical connection that is configured to deliver a second current from the top cell to the second contact. The platform cell is positioned between the top cell and the first bottom cell.

A sum of the first current and the second current may be approximately equal to a third current generated by the platform cell. The platform cell may include Si, and the first bottom cell may include a III-V material, a II-VI material, or an organic material. The first bottom cell may include GaSb. The top cell may include a perovskite material.

A bandgap of the first bottom cell may be smaller than a bandgap of the platform cell. The bandgap of the platform cell may be smaller than a bandgap of the top cell.

The first semiconductor type may be n-type and the second semiconductor type may be p-type. Alternatively, the first semiconductor type may be p-type and the second semiconductor type may be n-type.

The multijunction device may also include an interlayer between the first bottom cell and the first contact. The interdigitated contact layer may also include a third contact of the first semiconductor type and a fourth contact of the second semiconductor type, and the multijunction device may also include a second bottom cell that is electrically connected to the third contact. The first bottom cell and the second bottom cell may be connected to each other in parallel.

Other objects, advantages, and novel features of the present invention will become apparent from the following detailed description of the invention when considered in conjunction with the accompanying drawings.

### BRIEF DESCRIPTION OF THE DRAWINGS

FIG. 1 shows a multijunction solar cell according to an exemplary embodiment of the invention.

### DETAILED DESCRIPTION

Exemplary embodiments of the present invention relax the current matching requirements for multijunction solar cells while minimizing the number of terminals. The architecture significantly broadens the range of absorber materials and device structures of the individual cells that constitute the device.

A multijunction solar cell according to exemplary embodiments of the invention includes top and bottom cells, which are attached to a platform cell by full area contacts or partial area interdigitated contacts. The currents from the top and bottom cells enter the platform cell and additively closely match the current generated within the platform cell itself. One of the platform cell's back interdigitated contacts is used to extract the total current from the platform cell. The top and bottom cells have their own individual contacts, thus the device has at least three terminals. The bottom cells do not cover the full area of the platform cell, yet fully collect their designated photons due to engineered long-wavelength light trapping in the platform cell.

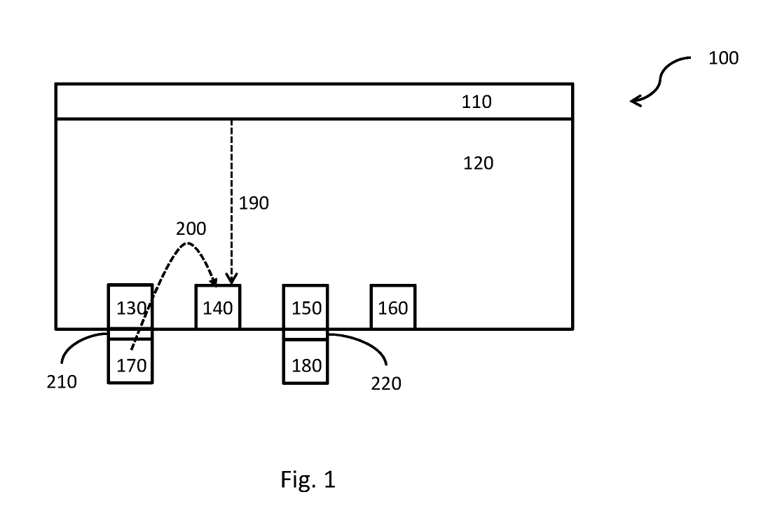

FIG. 1 shows a multijunction solar cell according to an exemplary embodiment of the invention. As shown in FIG. 1, the multijunction solar cell 100 includes a top cell 110 that is electrically connected to a platform cell 120. The platform cell 120 includes an interdigitated contact layer having contacts 130 and 150 of a first semiconductor type and contacts 140 and 160 of a second semiconductor type. In this embodiment, contacts 130 and 150 are n-type while contacts 140 and 160 are p-type; however, this may be reversed. A first bottom cell 170 is electrically connected to contact 130, and a second bottom cell 180 is electrically connected to contact 150. Although two bottom cells are shown in FIG. 1, the multijunction solar cell may include any suitable number of bottom cells. For example, bottom cells may be formed on one, some, or all of the contacts of the same semiconductor type, but not on the contacts of the other semiconductor type. In the embodiment shown in FIG. 1, the bottom cells 170 and 180 have a lower bandgap than the platform cell 120, and the bottom cells 170 and 180 are connected to each other in parallel. Further, there may be a first interlayer 210 between the bottom cell 170 and the contact 130. The first interlayer 210 is the opposite semiconductor type as the contact 130, thereby forming a tunnel junction that connects the bottom cell 170 with the platform cell 120 in series. Similarly, there may be a second interlayer 220 between the bottom cell 180 and the contact 150.

As shown in FIG. 1, the bottom cells 170 and 180 cover only part of the back surface of the platform cell 120, which may be made of a thick Si wafer. However, the long wavelength light below the Si bandgap is very efficiently trapped in the platform cell 120, and subsequently selectively absorbed in the bottom cells 170 and 180. This may be accomplished by texturing the top surface and/or the bottom surface of the platform cell 120. Alternatively, diffuse light scatters may be added to the bottom surface of the platform cell 120. For example, TiO₂ microparticles may be pressed against the bottom surface of the platform cell 120, thereby forming a “white paint” type of layer, preferably without an organic bonding agent. Various methods of trapping the long wavelength light in the platform cell 120 are described in B. G. Lee et al., “Light trapping by a dielectric nanoparticle back reflector in film silicon solar cells,” Applied Physics Letters 99, 064101 (2011), the entire disclosure of which is incorporated herein by reference.

If the bottom cells 170 and 180 are made of a suitable absorber material, such as GaSb, the bottom cells can generate 8 mA of current per every 1 cm² of the area of the platform cell 120. In the example shown in FIG. 1, a first electrical connection 200 is configured to deliver a first current from the bottom cell 170 to the contact 140. Specifically, the first current enters the platform cell 120 through contact 130. The first current is then collected by the contact 140. The first electrical connection 200 runs through the absorber material of the platform cell 120. The first current may be higher than 8 mA/cm², since the bottom cell 130 can absorb some photons with energies above the 1.1 eV bandgap of silicon.

Further, in the example shown in FIG. 1, the top cell 110 connects to the entire top surface of the platform cell 120, and generates a second current of 14 mA/cm². A second electrical connection 190 is configured to deliver the second current from the platform cell 120 to the contact 140. The second electrical connection 190 runs through the absorber material of the platform cell 120. The second current from the top cell 110 and the first current from the bottom cell 170 add up to approximately 22 mA/cm², which is collected by the contact 140. This three-terminal device is equivalent to a) a top cell and Si cell tandem (current 14 mA/cm²) and b) Si cell and the bottom cell tandem (current 8 mA/cm²), having a common terminal that collects the summary current of 22 mA/cm². This is approximately equal to a third current of 26 mA/cm² that is generated by the platform cell 120. Since it is possible to exceed the first current from the bottom cell 170 of 8 mA/cm², an almost perfect utilization of photons absorbed in the platform cell 120 can be achieved, leading for maximum performance of this 3-junction device, without a need to match the currents from top cell 110, the bottom cell 170, and the platform cell 120. The multijunction solar cell 100 may include repeating sets of components that behave in the same way. For example, the second bottom cell 180, the contact 150, and the contact 160 may interact with the corresponding portion of the top cell 110 in the same way as the first bottom cell 170, the contact 130, and the contact 140.

In the example shown in FIG. 1, the platform cell 120 is an n-type doped Si IBC cell. However, the platform cell 120 could also be a p-type doped Si IBC cell or an IBC cell made of a different absorber material. The platform cell 120 functions as an IBC cell, such that it separates electrons and holes generated by absorbed light, and collects them at the oppositely doped IBC contacts 130-160 (sending electrons to the n-type contacts and holes to the p-type contacts). In addition, to enable the bottom cells 170 and 180 to collect most of the lower-energy photons, the platform cell 120 should provide the necessary light trapping for these photons. This may achieved with a Si wafer cell.

The top cell 110 can be made of III-V materials such as InGaAs or GaAs, II-VI materials such as CdTe, perovskites, or other materials having a bandgap greater than the bandgap of the platform cell 120. The bottom cell 170 can be made of III-V materials, II-VI materials, organic materials, or other materials having a bandgap lower than the bandgap of the platform cell 120. The top cell 110 and the bottom cell 170 can be attached to the platform cell 120 by direct growth, wafer bonding, conductive adhesive, or any other suitable method that provides good electrical contact and optical transparency to prevent loss of photons in the structure.

The multijunction solar cell 100 may be used in a bifacial module. In this example, albedo light enters the platform cell 120 through the contacts 130-160, and metal grids are added to the contacts 130-160. This increases the power of the module by collecting the albedo light.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. A multijunction device comprising:
a top cell;
a platform cell that is electrically connected to the top cell, wherein the platform cell comprises an interdigitated contact layer having a first contact of a first semiconductor type and a second contact of a second semiconductor type;
a first bottom cell that is electrically connected to the first contact;
a first electrical connection that is configured to deliver a first current from the first bottom cell to the second contact; and
a second electrical connection that is configured to deliver a second current from the top cell to the second contact,
wherein the platform cell is positioned between the top cell and the first bottom cell.

2. The multijunction device according to claim 1, wherein a sum of the first current and the second current is approximately equal to a third current generated by the platform cell.

3. The multijunction device according to claim 1, wherein the platform cell comprises Si, and the first bottom cell comprises a III-V material, a II-VI material, or an organic material.

4. The multijunction device according to claim 3, wherein the first bottom cell comprises GaSb.

5. The multijunction device according to claim 1, wherein the top cell comprises a perovskite material.

6. The multijunction device according to claim 1, wherein a bandgap of the first bottom cell is smaller than a bandgap of the platform cell.

7. The multijunction device according to claim 6, wherein the bandgap of the platform cell is smaller than a bandgap of the top cell.

8. The multijunction device according to claim 1, wherein the first semiconductor type is n-type and the second semiconductor type is p-type.

9. The multijunction device according to claim 1, wherein the first semiconductor type is p-type and the second semiconductor type is n-type.

10. The multijunction device according to claim 1, further comprising an interlayer between the first bottom cell and the first contact.

11. The multijunction device according to claim 1, wherein:
the interdigitated contact layer further comprises a third contact of the first semiconductor type and a fourth contact of the second semiconductor type, and
the multijunction device further comprises a second bottom cell that is electrically connected to the third contact.

12. The multijunction device according to claim 11, wherein the first bottom cell and the second bottom cell are connected to each other in parallel.

13. The multijunction device according to claim 11, wherein the first semiconductor type is n-type and the second semiconductor type is p-type.

14. The multijunction device according to claim 11, wherein the first semiconductor type is p-type and the second semiconductor type is n-type.
